(19) United States
(12) Patent Application Publication
(10) Pub. No.: US 2025/0138775 A1
(43) Pub. Date: May 1, 2025

(54) Method and Apparatus for Control and Transfer of Audio Between Analog and Computer in Digital Audio Processing

(71) Applicant: Aran Gallagher, Victoria (AU)

(72) Inventor: Aran Gallagher, Victoria (AU)

(73) Assignee: Freqport Pty Ltd, Victoria (AU)

(21) Appl. No.: 18/941,782

(22) Filed: Nov. 8, 2024

Related U.S. Application Data
(63) Continuation of application No. PCT/AU2023/050388, filed on May 9, 2023.

(30) Foreign Application Priority Data
May 9, 2022 (AU) 2022901228

(51) Int. Cl. G06F 3/16

(52) U.S. Cl. CPC G06F 3/162; G06F 3/165

(57) ABSTRACT

A method for control and transfer of audio between analog and computer in digital audio processing including one or a combination of a. controlling data by converting to- and -from analog to control the analog circuit and b. time correction in analogue and digital audio processing with a communication line using USE connection between analog processor and digital computer processor.

### CROSS-REFERENCE TO RELATED PATENT APPLICATIONS

This Patent Application is a Continuation of PCT Patent Application No. PCT/AU2023/050388, filed May 9, 2023, which designated the United States. PCT Patent Application No. PCT/AU2023/050388 and this application claim the benefit of Australian Patent Application No. 2022901228, filed May 9, 2022. The entire teachings and disclosures of each application are incorporated herein by reference thereto.

### FIELD OF THE INVENTION

The present invention relates to a method and apparatus for control and transfer of audio between analog and computer in digital audio processing. It is particularly related to time correction in analog and digital audio processing.

The invention has been developed primarily for use in/with USB connection and will be described hereinafter with reference to this application. However, it will be appreciated that the invention is not limited to this particular field of use.

### BACKGROUND OF THE INVENTION

Audio processed with analog circuitry sounds amazing, but using analog equipment in your workflow is, and has always been difficult. Most music produced now-days uses digital processing of mathematical equations to generate and process audio. This can make the audio sound ‘flat’ and ‘dull’.

Analog is a hassle with problems such as setting up analogue cabling and figuring out how to configure the software and audio interface can take hours. This is a major deterrent to the use of analog. Further If you want to come back and use your analog kit again later it is likely the knobs and setup will be different—this makes it very difficult to replicate the same sound again.

Music Plugin Sales are up 151% over last 10 years. The popularity of EDM and other electronic music genres has contributed to the demand for this broad product portfolio, particularly analog instruments. Professional Studios often want analog sound but can't afford time and effort setting up an maintaining a full analog studio.

It can be seen that known prior art of combined audio processing of Digital and Analog audio processing has the problems of:
a) connectivity
b) set-up replication
c) communication through A/D and D/A
d.) glitch free clock synchronisation at low latency
e) maintain synchronization

The present invention seeks to provide Method and Apparatus for control and transfer of audio between analog and computer in digital audio processing. It particularly includes Time Correction in Analog and digital audio processing. The invention aims to overcome or substantially ameliorate at least one or more of the deficiencies of the prior art, or to at least provide an alternative.

It is to be understood that, if any prior art information is referred to herein, such reference does not constitute an admission that the information forms part of the common general knowledge in the art, in Australia or any other country.

### SUMMARY OF THE INVENTION

According to a first aspect of the invention there is provided a method for control and transfer of audio between analog and computer in digital audio processing including one or a combination of controlling data by converting to- and-from analog to control the analog circuit and time correction in analogue and digital audio processing wherein a communication line using USB connection between analog processor and digital computer processor.

Adding the capability of digital control of the analog circuit from the Host computer it is highly desirable. This is highly desirable because it enables functionality such as recall of analog settings initiated from the host, and automating the control of the analog circuitry from within the host software. Each time the host software, or plugin is used after saving the settings then the settings can be recalled, or automated thereafter.

In one preferred form the invention provides a method of controlling data by converting to- and-from analog to control the analog circuit includes audio sent from host and is eventually converted by DAC to analog audio. This audio is processed using analog processing hardware (i.e analog circuit such as analog filters, reverb hardware, tape processing, vacuum tubes, analog delay circuit, optical processing of audio, transformers, etc.,), and this hardware is controlled by communicated signals.

The analog block processes audio using any form of analog processing or circuitry, and this circuit is controlled by control signals that are outputs and inputs of analog voltage or current to control the analog processing block that in turn changes the analog processing.

According to form of the present invention, there is provided a method for time correction in analogue and digital audio processing with USB connection between digital processor having original audio and processing audio hardware including the steps of:
a. Providing a host computer with source audio
b. Assessing audio clock timing of time processing on the host computer of the source audio
c. Providing a USB connection between the host computer and an ancillary processing audio hardware
d. the communication channel along the USB connection providing a time correction to the endpoint processing to enable clock synchronisation of the processing on the host computer and the ancillary processing audio.

The host computer can be Desktop Computer, Laptop, Mobile device, Tablet or cloud computing hardware.

The source audio can be any audio for processing in the computer and therefore can be recorded audio or direct from virtual instrument.

The method can include
a) providing a USB connection in isochronous mode between the digital processor and the processing audio hardware;
b) Adding a communication channel over USB wherein the communication channel provides a time correction to enable clock synchronisation of the processing along the USB connection in isochronous mode.

The invention achieves synchronisation without a global clock by the time correction to enable clock synchronisation includes the steps of:
a) Measuring clock rate of original audio on digital processor
b) Measuring clock rate of hardware processing audio
c) Comparing the measured clock rate of hardware processing audio and the measured clock rate of audio
d.) Adjusting clock rate of hardware processing to create ADJUSTMENT MESSAGE to match clock rate of audio
e.) Sending ADJUSTMENT MESSAGE over the communication channel over the USB
   Wherein the endpoint processing of processing audio hardware is synchronised without a universal clock.

It can be seen that the invention of method and apparatus for time correction provides the benefit of easy combination of synchronised digital and analogue processing.

Method of the clock synchronisation steps includes:
a) Audio Callback every block of samples from USB audio driver (AC)
b) Calculate accumulated drift offset per counter meter=(dd)/(cm) where dd=deviation in samples from 50% buffer level of each audio buffer in audio from application on channel x
c) Determining if (dd) is below or above emergency threshold
d) If yes, send emergency ADJUSTMENT MESSAGE
e) Determining if multi-instance (multi-channel) alignment (MCA) is required by assessing if level of each used audio buffer from application on channel ‘x’ empty or full AND is alignment allowed now
f) Perform MCA by either skip or repeat samples in mis-aligned channel, or by enabling audio sample rate conversion during a realignment process.

Simple Compensation steps include:
a) At regular time interval longer than AC, preferably 100× longer than sample interval, assess average drift measure (AM=dd/cm), and reset cm counter and accumulated dd
b) Limit magnitude of AM to minimise jitter below audio frequency to new value JM and
c) send ADJUSTMENT MESSAGE (ADJ=JM).

The processing audio hardware includes analogue audio processing and requires control data to be sent from within the digital software to the end analogue device, converted from digital to analogue, processed in the analogue domain by that device then converted back to digital and sent back the host software wherein the endpoint processing of processing audio hardware is synchronised without a universal clock all while maintaining accurate and glitch free clock synchronisation at low latency.

It can be seen that the invention of method and apparatus for time correction in analogue and digital audio processing provides the benefit of combining the very best of analogue sound with ease of digital workflow to facilitate the creation of a warmer sound, more enjoyable and tactile experience that musicians, and music producers require.

It can be seen that in one form the invention achieves an aim of:
Pure Analog—Real analogue processing inside your digital software (not digitally emulated). By adding control block (m) analogue circuits require signals to control levels. A communication channel over USB is used to send and receive control data. The control data is converted in block m to- and-from analog to control the analog circuit.
Effortless—Just plug in the product with a single USB cable, open the interface and play.
Tactile Fun—Knobs to tweak. Touch and feel the creative process. Flexible control of Analogue Signals.
Total Recall—Record and playback changes to analog parameters. Your setup will be the same next time you open the software.

The invention allows products which are analogue hardware processors to be connected simply by USB. The platform enables analogue equipment to be used as software plugins and instruments inside music software or as standalone software. This creates a brand-new category of products for musicians, producers and audio lovers.

Other aspects of the invention are also disclosed.

### BRIEF DESCRIPTION OF THE DRAWINGS

Notwithstanding any other forms which may fall within the scope of the present invention, a preferred embodiment/preferred embodiments of the invention will now be described, by way of example only, with reference to the accompanying drawings in which:

FIG. 1 is a diagrammatic view of the system of the invention and its adaptation to use analogue audio systems.

FIG. 2 is a diagrammatic example system of FIG. 1 in the form of a USB connectable Quad Analog Tube Multi Instance Hardware Plugin having software connectable to hardware with an addin in module that can be integral with or plugin to the hardware to Time Correction in Analog and digital audio processing in accordance with a preferred embodiment of the present invention.

FIG. 3 is a diagrammatic illustration of the electronic connections by a USB connectable computer and analog hardware processor with possible addin module that can be inserted or integral with the analog hardware processor in accordance with a preferred embodiment of the present invention.

FIG. 4 is a illustrative detail of Module A and interaction over USB with Processor Z.

FIG. 5 is an illustrative detail of Processor Z and direct interaction with block M.

FIG. 6 is a diagrammatic illustration of the software architecture running on the host computer in accordance with a preferred embodiment of the present invention.

FIG. 7 is a diagrammatic view of the software interface taken from a real use scenario of a preferred embodiment of the present invention.

FIG. 8 is a rear diagrammatic view of a processing analogue hardware for USB connection of a preferred embodiment of the present invention.

FIGS. 9 to 13 are diagrammatic block diagrams of a method for time correction in analogue and digital audio processing with USB connection between digital processor having original audio and processing audio hardware in accordance with a preferred embodiment of the present invention.

### DESCRIPTION

It should be noted in the following description that like or the same reference numerals in different embodiments denote the same or similar features.

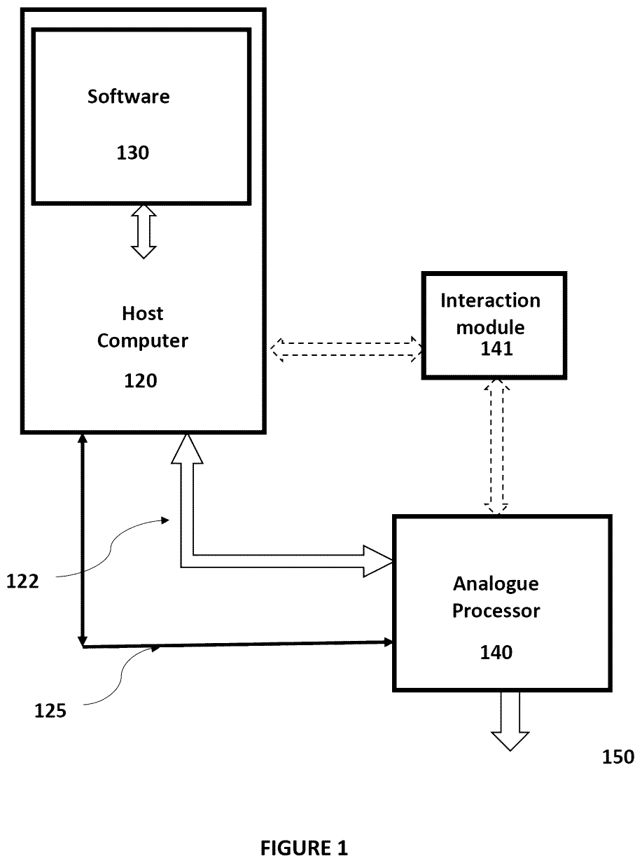

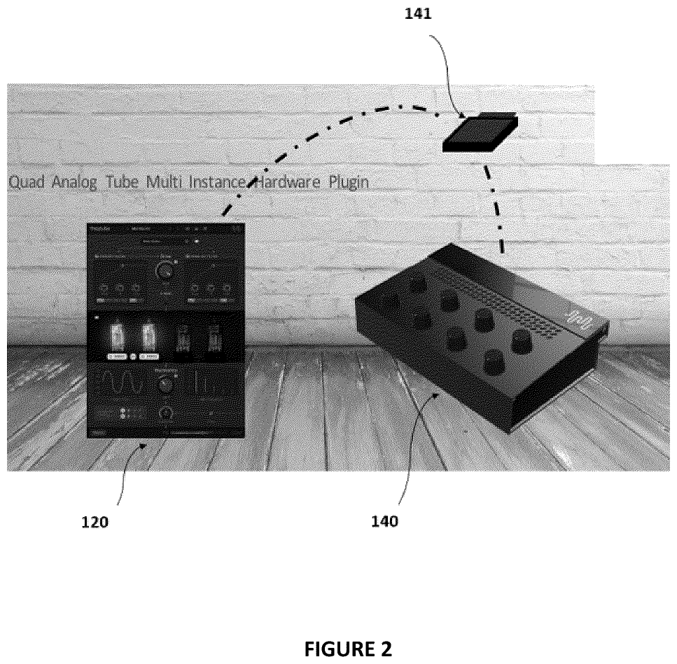

Referring to the drawings there is shown in FIGS. 1 and 2 a USB connection 125 of host computer 120 with software 130 to processing analogue hardware 140. The computer 120 or host represents software app which can be a plugin, a virtual instrument, or a standalone application and is thereby running on the host system. It is connected to the analogue processor 140 by an add-in module 141 that can be a plugin subcircuit or be integral with the processing hardware 140 that is adapted to interface through the hardware plugin module or integral subcircuit. The plugin module or integral subcircuit 141 can include some of the operative parts of the analogue processing hardware 140. The product functions in block 141 may be used as a module that can be sold as a product within its own right, or embedded within the product.

Therefore the system can be applied to any audio analogue device and improve connection, versatility and accuracy through the combination of one or more of:
a) clock control without universal clock

There is provided a method for time correction in analogue and digital audio processing with USB connection between digital processor, computer or host having original audio and processing audio hardware.

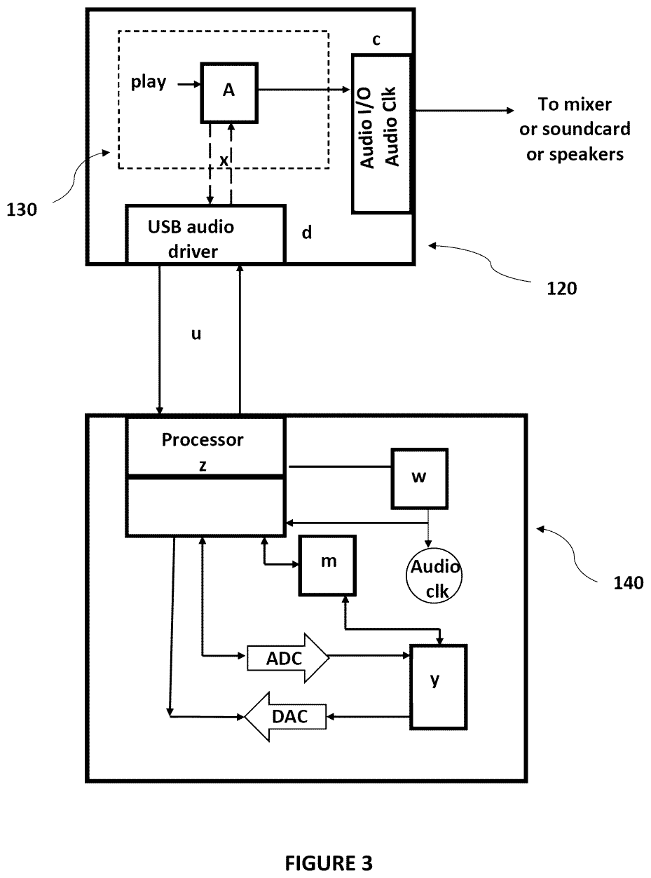

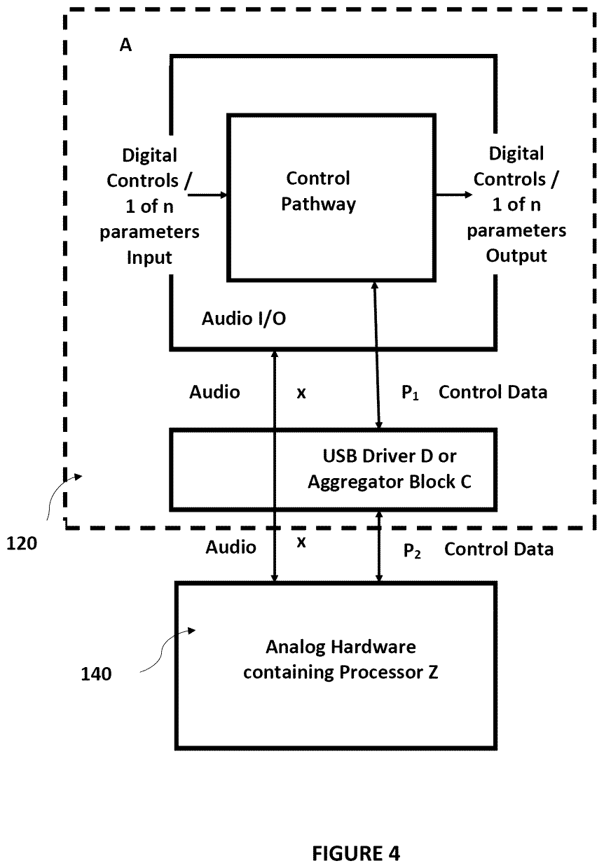

As per FIGS. 3, 4 and 5, in general the system provides host computer 120 running software 130 with source audio, assesses audio clock timing of processing of source audio on the host computer, uses the USB connection through the USB audio driver between the host computer and the ancillary processing audio hardware 140 by the communication channel u to provide a time correction to the endpoint processing y to enable clock synchronisation of the processing on the host computer 120 and the analogue processing audio hardware 140.

The host computer 120 has software 130 containing audio function block (A) that provides the audio source (x) etc., The host computer 120 has audio function (A) that provides bidirectional audio source (x), which is connected to USB audio driver (d) for connection over channel (u) to and from the and connected ancillary analogue processing audio 140. The audio function (A) provides bidirectional audio source (x) which can send and receive back the analogue processed audio from the analogue processing audio hardware 140 is also connected to input output audio for sending to or receiving from external audio components such as mixers, soundcards such as on virtual instruments or speakers.

The audio and ancillary processing 140 has Analogue to Digital Convertor (ADC) and Digital to Analogue Convertor (DAC) so that the audio can be processed in analogue at the endpoint analogue audio circuit (y).

(m) of the ancillary processor takes control data sent from A by the USB audio driver (d) over (u) to Processor (z) then translates into analogue signals to control circuit (y).

There is also (w) which is the glitch-less adjustable clock that generates Audio clk used for hardware audio. (w) is controlled through (z) by the ADJUSTMENT MESSAGE directly, or by PLL methods.

Software running in either block A, B, C or D contains a software algorithm that measures audio clock from computer (c) and compares measured timing with audio timing of USB audio driver (d). Using the algorithm the difference in timing is calculated and sends an ADJUSTMENT MESSAGE to processor (z). Processor (z) responds to ADJUSTMENT MESSAGE and changes the clock frequency of w to match the computer. The result is that Audio Clk (in block 141) matches the Audio I/O Audio Clk in block (c).

The analog block (y) processes audio using any form of analog processing or circuitry, and this circuit is controlled by control signals that are output from block (m). The control block (m) outputs and inputs analog voltage or current to control the analog processing block that in turn changes the analog processing in some way (example; change an analog audio filter cut-off, analog biasing of vacuum tube, change analog delay timing, level of saturation into an audio transformer etc.).

Furthermore the processor z (or any path within block 141) may also contain DSP audio processing. In the case of DSP processing the control signals for such processing shall be carried over USB and may be in the same form as control signals that originate (or are destined) from block m.

The control function block has digital control inputs and outputs inside software on host computer (A) are collected and sent as control data over USB over paths P1 and P2 to the analog hardware via the USB driver (D), and optionally via the aggregator application (C). The control data sent over may be sent over either P1 or P2 as either custom data packets, or as a MIDI representation of the control data. Adding the capability of digital control of the analog circuit from the Host computer it is highly desirable. This is highly desirable because it enables functionality such as recall of analog settings initiated from the host, and automating the control of the analog circuitry from within the host software. Each time the host software, or plugin is used after saving the settings then the settings can be recalled, or automated thereafter.

The USB audio and control paths are related by the following:

Audio sent from host as (x) is eventually converted by DAC to analog audio in block y. Then this audio is processed within block y using analog processing hardware (i.e analog circuit such as analog filters, reverb hardware, tape processing, vacuum tubes, analog delay circuit, optical processing of audio, transformers, etc.), and this hardware is controlled by signals from block m.

Block 140 may also contain generation of analog control signals that are converted from analog to digital control signals in block m, then forwarded to the host (through blocks d to A or B).

Audio that is processed within block y analog processing hardware is then output to ADC and then into processor z then sent to host over USB and into d and A or B.

Control signals are controls for the analog processing hardware. Control signals are sent over the USB connection as digital control messages between blocks m, z, u, d and A or B (optionally via block C), and then converted to and from analog voltages (and/or currents) in block m by using a control-DAC (for control outputs) and control-ADC (for control inputs). When describing the control-ADC or control-DAC its important to note that these are contained within block m and this is not the same path where ADC and DAC are connected to processor z and used for the analog audio hardware processing. Processor z receives and sends the control signals in their digital form to and from the host (block d and also block A (or B) through to block m. Block m converts the control signals to and from analog voltage (or currents) that in turn control the analog circuit in block y. Block 140 may also contain generation of analog control signals that are converted to control signals in block m then forwarded to the host (through blocks d).

Any of the blocks m, y, z may or may not be internal to the product.
This means for example that we could make a product that does not include y but does include the analog control signals generated in m, in this case the product interfaces with an external product (from any manufacturer) and that external product contains the functions of y.

A further example could be that we do not include ADC or DAC blocks and sell product with only z and m. Any combination of these inclusions or exclusion of each block should apply.

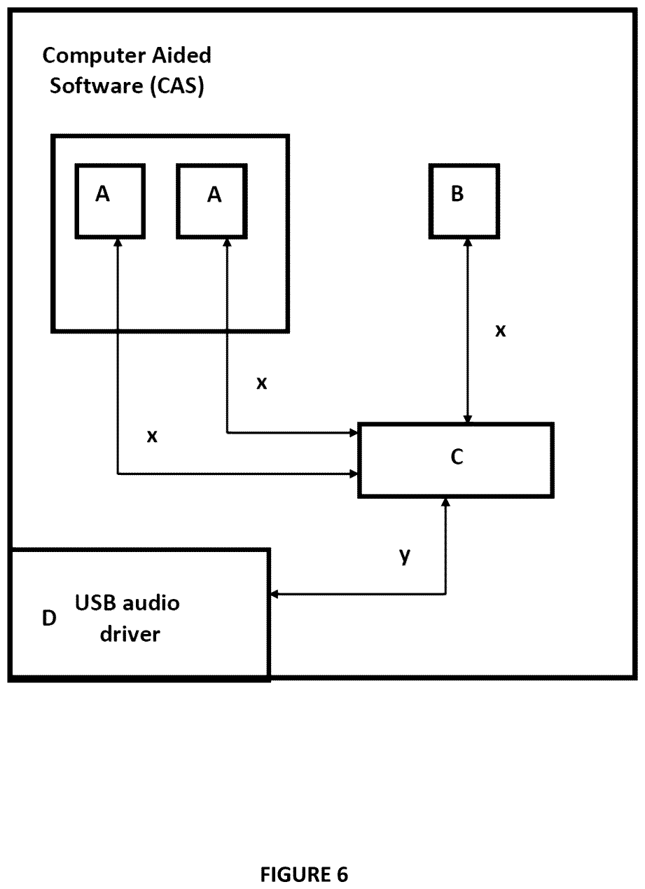

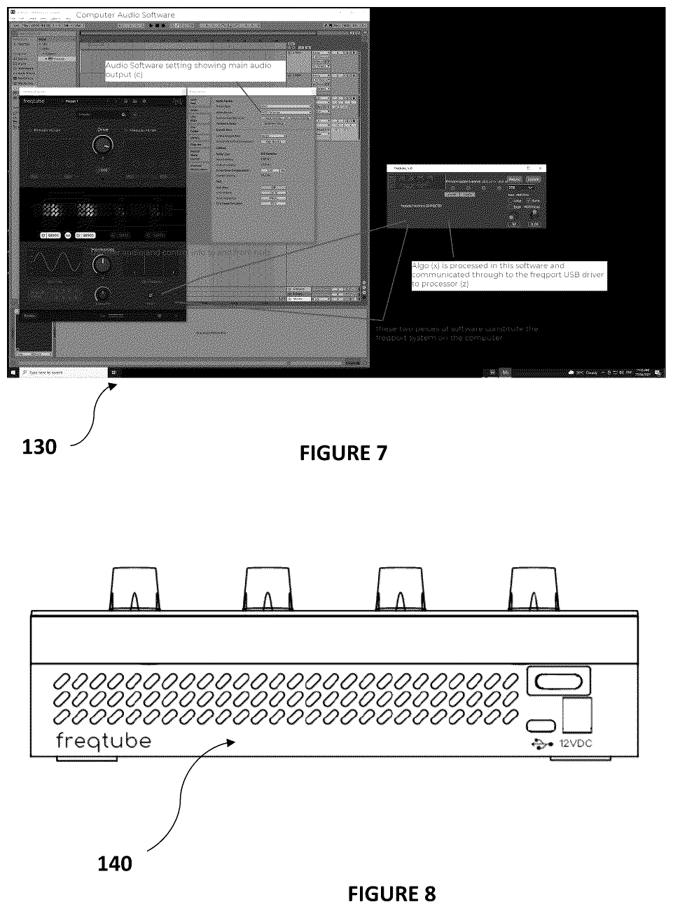

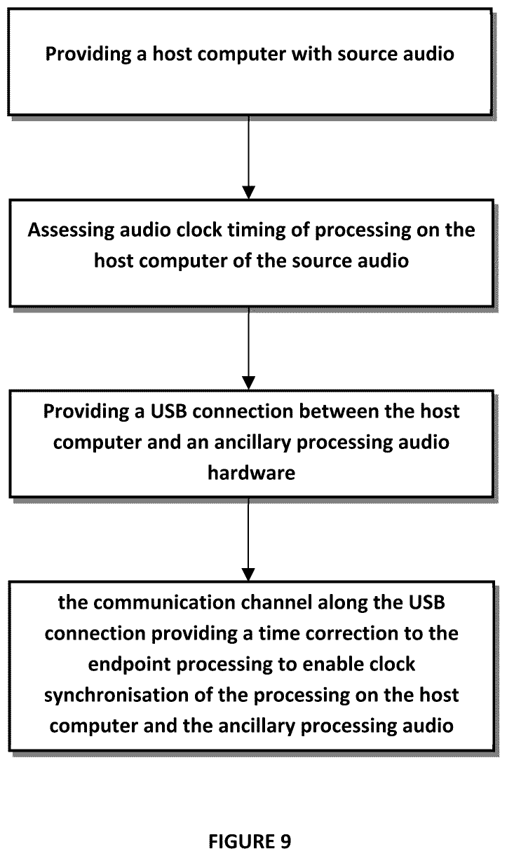

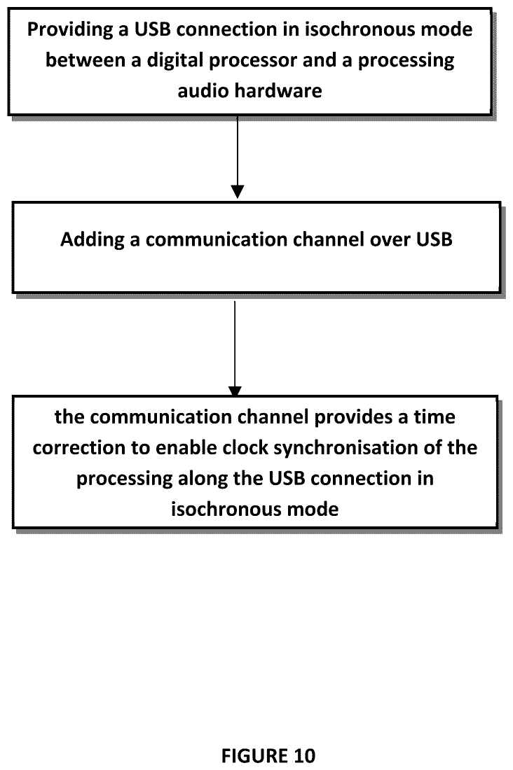

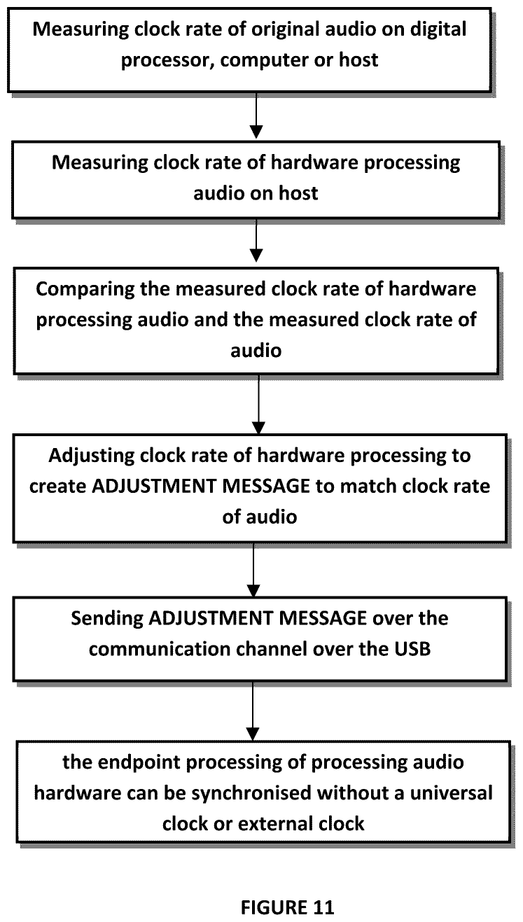

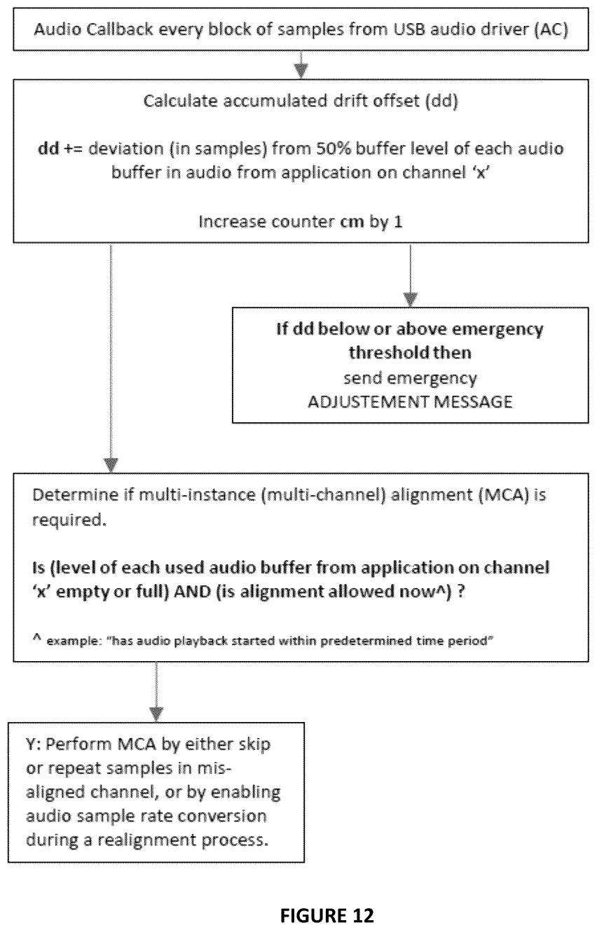

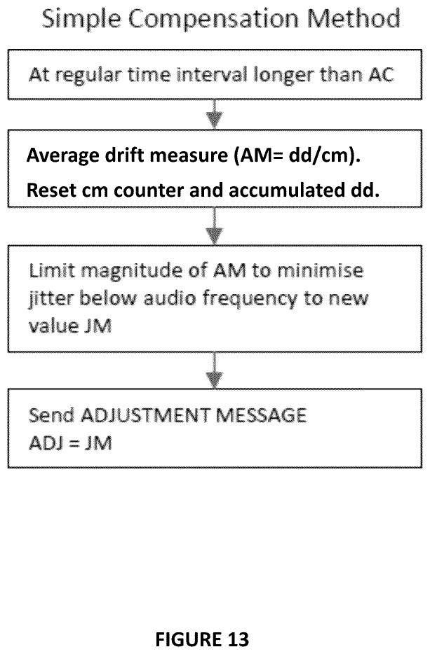

Referring to FIG. 6, in one form this includes the steps of:
Providing a USB connection in isochronous mode between the digital processor and the processing audio hardware;
Adding a communication channel over USB
wherein the communication channel provides a time correction to enable clock synchronisation of the processing along the USB connection in isochronous mode.

However in other forms there is a bulk transfer mode that can be used to transfer the audio data at a rate related to the Audio I/O clock.

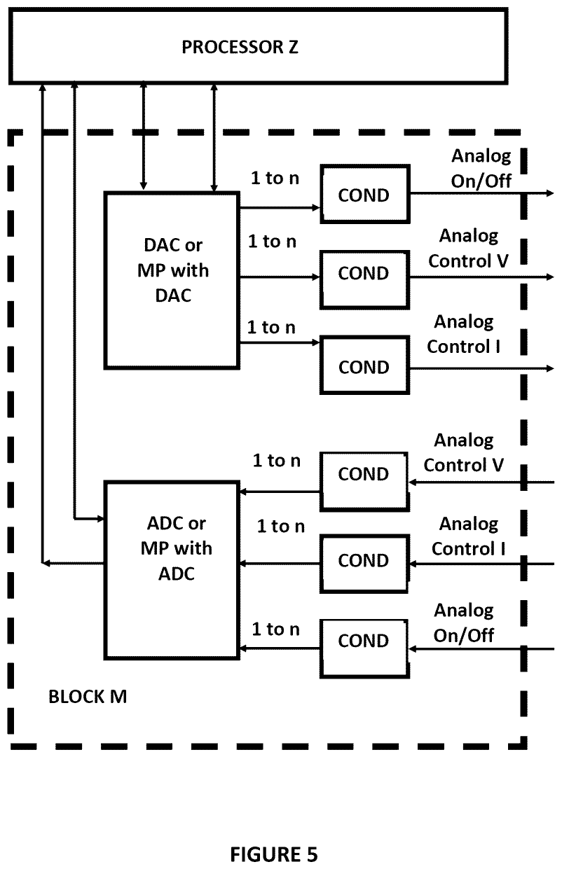

Referring to FIGS. 5 and 6 there is shown how the software on the computer interact

The primary application to playout processed audio runs on the host computer as either:
1. a software plugin, or virtual instrument (A) running inside a third-party Computer Audio Software application (CAS),
2. or as a dedicated standalone application (B) which effectively has CAS integral and elements of (A).

Block A represents audio that is sent or received within computer software (examples are; audio to and from an AU, VST, AAX plugin hosted within a digital audio workstation (DAW)). Multiple instances of this audio can be present in the host. Multiple instances are represented by separate audio streams between A to and/or from the USB audio driver D. Streams may pass directly from an instance A to the audio USB driver D, or through aggregator block C. (block C is also called an applet or Hub).

Block A there can be any number of instances (1,2 . . . ).

Block C is aggregation block that combines and splits audio streams from D into separate streams. Block C may be bypassed and instead audio sent or received directly to block D.

Block B represents some application, driver or process on the Host that directly process the audio stream in a self-contained way. This is differentiated by Block B so that it processes audio as plugins with a DAW.

Audio and ancillary data is sent between the host software and hardware through USB audio driver D with intermediate processing performed by aggregation block (.C). The Applet or Hub (C) aggregates all x channels to send to USB audio driver via y and calculates the ADJUSTMENT MESSAGE. Functions performed in (.C) may also be integrated within driver application (D), or within (A) or (B).

The time correction to enable clock synchronisation includes the steps of:
a) Measuring clock rate of original audio on digital processor
b) Measuring clock rate of hardware processing audio
c) Comparing the measured clock rate of hardware processing audio and the measured clock rate of audio
d) Adjusting clock rate of hardware processing to create ADJUSTMENT MESSAGE to match clock rate of audio
e) Sending ADJUSTMENT MESSAGE over the communication channel over the USB
f) Wherein the endpoint processing of processing audio hardware is synchronised without a universal clock.

The clock synchronisation steps include:
a) Audio Callback every block of samples from USB audio driver (AC)
b) Calculate accumulated drift offset per counter meter=(dd)/(cm) where dd=deviation in samples from 50% buffer level of each audio buffer in audio from application on channel x
c) Determining if (dd) is below or above emergency threshold
d) If yes, send emergency ADJUSTMENT MESSAGE
e) Determining if multi-instance (multi-channel) alignment (MCA) is required by assessing if level of each used audio buffer from application on channel ‘x’ empty or full AND is alignment allowed now
f) Perform MCA by either skip or repeat samples in mis-aligned channel, or by enabling audio sample rate conversion during a realignment process.

The Simple Compensation steps include:
a) At regular time interval longer than AC, preferably 100× longer than sample interval, assess average drift measure (AM=dd/cm), and reset cm counter and accumulated dd
b) Limit magnitude of AM to minimise jitter below audio frequency to new value JM and
c) send ADJUSTMENT MESSAGE (ADJ=JM).

### Solution 1:

a) Using USB 2.0 Audio running in Isochronous mode (recognised as highest quality and professional method of USB audio transfer) we add a communication channel over USB to adjust the clock rate of the endpoint in a controlled and artifact free way and importantly removing clock jitter from the audio frequencies.

It can be seen that this is done by:
a) Measuring clock rate of audio in host and compare with the audio clock running on the hardware.
b) Adjusting (ADJ) hardware audio clock to match host clock using Algo. Send the ADJ data over USB to the endpoint then control endpoint clock.

### Description of Algorithm:

a) Algorithm has multiple options of operation: PID feedback mode, ASRC mode and simple drift compensation mode. Proportional, Integral, Derivative. (PID) control provides a continuous variation of output within a control loop feedback mechanism to accurately control the process, removing oscillation and increasing process efficiency
b) Algorithm has emergency buffer mode where samples can be repeated or skipped if over or underruns may occur.
c) Algorithm has multi instance sync method that aligns audio channel buffers at certain times, either using audio skip/repeat, or using ASRC (audio sample rate conversion).

### Solution 2:

a) Same as Solution1 but instead using USB 2.0 Audio running in adaptive mode (high jitter).

### Solution 3:

a) Same as Solution1 but instead using USB bulk data transfer. In this solution the algorithm for calculation of ADJUSTMENT MESSAGE may be performed in hardware processor z.

In operation with reference to FIG. 2 the computer 120 having software 130 and outward connections including by USB audio driver over channel u to processing audio hardware 140.

Operating Analogue equipment inside host digital software (without changing the user's workflow) requires audio and control data to be sent from within the digital software to the end analogue device y, converted from digital to analog, processed in the analog domain by that device then converted back to digital and sent back the host software all while maintaining accurate and glitch free clock synchronisation at low latency.

The analogue device may also have multiple audio processing circuits and audio channels, these need to be processed in a multi-instance method and maintain synchronization between each channel.

In this setup there is audio software A, B, C, or D with algorithm and with main audio output to mixer or soundcard or speakers selected in the audio software. The USB audio driver is connected to the audio software. (either through intermediate applet (C) or directly to (A) or (B)).

The software algorithm measures audio clock from computer (c) and compares measured timing with audio timing of USB audio driver (d). The algorithm calculates the difference in timing and sends an ADJUSTMENT MESSAGE (using USB data) to processor z in the processing audio hardware 140.

The processor z responds to the ADJUSTMENT MESSAGE and changes the clock frequency of w in the processing hardware 140 so as to match.

Software that runs inside host software (plugin, virtual instrument or applet or standalone application). This applet routes the audio to and back from the end point analog processing device. Importantly the audio at the end point is synchronised from timing measured in this applet.

It can be seen therefore that audio at point (x) is synchronized with audio at point (z) and (w) without a universal clock but by measuring offset and sending an adjustment over USB connection. It allows keeping host audio clock synchronised with endpoint analog processing device at low latency without a universal clock or external clock.

### EXAMPLE

A first product as an embodiment of the invention has 4 independent tube channels, two tube types, parallel and primary analog processing paths for each channel. Perfect for warming up any digital sound, mastering, or production use.

### Additional Specifications

| | |
|---|---|
| Power Input | 24 W DC power adaptor. Use only Freqport adaptor. |
| Adaptor | 100Vac.-240Vac, 50/ |
| Mains | 60 Hz |
| Ambient | 0 to 50 C. |
| Temperature | |
| Range | |
| USB | Type - C |
| Pro Converters | 120 dB DNR 32 bit DAC, |
| | 116 dB DNR 32 bit ADC |
| Dimensions | Unit: 205 mm × 130 mm × 50 mm (W × H × D) |
| | Boxed: 350 mm × 190 mm × 80 mm (W × H × D) |
| Weight | Unit: 810 g |
| | Boxed: (1.43 kg) |
| Control and | Full Color Display, 8 assignable knobs, Power switch |
| Indication | |
| Optional Extras | Rockmount kit. |

### Setup:

Connect to host using only a USB-C cable. High voltage internal tube
driver circuits.
High end pro-grade 32 bit converters capable of 120 dB DNR up to 192
kHz sample rate.
2 × E83CC/12AX7 high gain top quality tubes
2 × 12AU7 mid gain pre amplifier tubes for softer character. Overdrive
option with clipping detection.
Assignable knobs for tactile tweaking of analog parameters.
Analog gain, mixing, drive, phase control and harmonics control. Primary
and parallel multi-mode hardware filters.
Multi-Instance (run up to 4 plugin instances at one time anywhere in your
digital workflow).
Seamless bit perfect audio transfers into your digital workflow
Recall of all analog parameters - each time you revisit your mix the
settings will be the same!

### Interpretation

### Embodiments

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the above description of example embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the Detailed Description of Specific Embodiments are hereby expressly incorporated into this Detailed Description of Specific Embodiments, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

### Different Instances of Objects

As used herein, unless otherwise specified the use of the ordinal adjectives “first”, “second”, “third”, etc., to describe a common object, merely indicate that different instances of like objects are being referred to, and are not intended to imply that the objects so described must be in a given sequence, either temporally, spatially, in ranking, or in any other manner.

### Specific Details

In the description provided herein, numerous specific details are set forth. However, it is understood that embodiments of the invention may be practiced without these specific details. In other instances, well-known methods, structures and techniques have not been shown in detail in order not to obscure an understanding of this description.

### Terminology

In describing the preferred embodiment of the invention illustrated in the drawings, specific terminology will be resorted to for the sake of clarity. However, the invention is not intended to be limited to the specific terms so selected, and it is to be understood that each specific term includes all technical equivalents which operate in a similar manner to accomplish a similar technical purpose. Terms such as “forward”, “rearward”, “radially”, “peripherally”, “upwardly”, “downwardly”, and the like are used as words of convenience to provide reference points and are not to be construed as limiting terms.

### Comprising and Including

In the claims which follow and in the preceding description of the invention, except where the context requires otherwise due to express language or necessary implication, the word “comprise” or variations such as “comprises” or “comprising” are used in an inclusive sense, i.e. to specify the presence of the stated features but not to preclude the presence or addition of further features in various embodiments of the invention.

Any one of the terms: including or which includes or that includes as used herein is also an open term that also means including at least the elements/features that follow the term, but not excluding others. Thus, including is synonymous with and means comprising.

### Scope of Invention

Thus, while there has been described what are believed to be the preferred embodiments of the invention, those skilled in the art will recognize that other and further modifications may be made thereto without departing from the spirit of the invention, and it is intended to claim all such changes and modifications as fall within the scope of the invention. For example, any formulas given above are merely representative of procedures that may be used. Functionality may be added or deleted from the block diagrams and operations may be interchanged among functional blocks. Steps may be added or deleted to methods described within the scope of the present invention.

Although the invention has been described with reference to specific examples, it will be appreciated by those skilled in the art that the invention may be embodied in many other forms.

### INDUSTRIAL APPLICABILITY

It is apparent from the above, that the arrangements described are applicable to the digital and analog audio processing industries.

1. A method for control and transfer of audio between analog and computer in digital audio processing including one or a combination of
a. controlling data by converting to- and-from analog to control the analog circuit and
b. time correction in analogue and digital audio processing
wherein a communication line using connection between analog processor and digital computer processor using a continuous stream of audio data divided into small buffers, and transmitted over the communication line, to ensure real-time feedback and interaction using a continuous stream of audio data and/or control data divided into small buffers for transmission over the connection, providing real-time auditory feedback and interactive device control and response.

2. A method according to claim 1 wherein the communication line uses USB.

3. A method according to claim 1 wherein the controlling data by converting to- and-from analog to control the analog circuit includes:
a. by converting to- and-from analog to control the analog circuit includes audio sent from host and is eventually converted by DAC to analog audio,
b. This audio is processed using analog processing hardware (i.e analog circuit such as analog filters, reverb hardware, tape processing, vacuum tubes, analog delay circuit, optical processing of audio, transformers, etc.), and this hardware is controlled by communicated signals,
c. The analog block processes audio using any form of analog processing or circuitry,
d. and this circuit is controlled by control signals that are output are outputs and inputs of analog voltage or current to control the analog processing block that in turn changes the analog processing.

4. A method according to claim 1 wherein the controlling data by converting to- and-from analog to control the analog circuit includes
a. Audio sent from host at x is eventually converted by DAC to analog audio in analog block y.
b. this audio is processed within analog block y using analog processing hardware (i.e analog circuit such as analog filters, reverb hardware, tape processing, vacuum tubes, analog delay circuit, optical processing of audio, transformers, etc.), and this hardware is controlled by signals from block m.
c. the encapsulated hardware Block (140) uses signals purely generated in analog such as from synthesizers or sound generators and may also contain generation of analog control signals that are each converted from analog to digital control signals in block m, then forwarded to the host (through block d).
d. Audio that is processed within block y analog processing hardware is then output to ADC and then into processor z on hardware block then sent to host over USB and into USB Driver (d and or x).

5. A method of claim 1 wherein the analog block (y) processes audio using any form of analog processing or circuitry, and this circuit is controlled by control signals that are transmitted between analog to digital or digital to analog by signal converter control block (m) and host through driver block (d) and outputs and inputs analog voltage or current to control the analog processing block that in turn changes the analog processing.

6. A method according to claim 5 including Block C which is an aggregation block that combines and splits audio streams from D into separate streams, but block C may be bypassed and instead audio sent or received directly to block D wherein Audio and ancillary data is sent between the host software and hardware through audio driver D with intermediate processing performed by aggregation block (C) and the Applet or Hub (C) aggregates all x channels to send to audio driver via y.

7. A method according to claim 2 wherein the time correction in analogue and digital audio processing with USB connection between digital processor having original audio and processing audio hardware includes the steps of:
a. Providing a host computer with source audio,
b. Assessing audio clock timing of processing on the host computer of the source audio
c. Providing a USB connection between the host computer and an ancillary processing audio hardware,
d. the communication channel along the USB connection providing a time correction to the endpoint processing to enable clock synchronisation of the processing on the host computer and the ancillary processing audio.

8. A method according to claim 2 wherein:
a. a USB connection is provided in isochronous mode between the digital processor and the processing audio hardware;
b. and includes adding a communication channel over USB,
c, wherein the communication channel provides a time correction to enable clock synchronisation of the processing along the USB connection in isochronous mode.

9. A method according to claim 8 wherein the time correction to enable clock synchronisation includes the steps of:
a. Measuring clock rate of original audio on digital processor,
b. Measuring clock rate of hardware processing audio,
c. Comparing the measured clock rate of hardware processing audio and the measured clock rate of audio,
d. Adjusting clock rate of hardware processing to create ADJUSTMENT MESSAGE to match clock rate of audio,
e. Sending ADJUSTMENT MESSAGE over the communication channel over the USB,
f. Wherein the endpoint processing of processing audio hardware is synchronised without a universal clock.

10. Method according to claim 9 wherein the clock synchronisation steps includes:
a. Audio Callback every block of samples from USB audio driver (AC),
b. Calculate accumulated drift offset per counter meter=(dd)/(cm) where dd=deviation in samples from 50% buffer level of each audio buffer in audio from application on channel x,
c. Determining if (dd) is below or above threshold,
d. If yes, send emergency ADJUSTMENT MESSAGE,
e. Determining if multi-instance (multi-channel) alignment (MCA) is required by assessing if level of each used audio buffer from application on channel ‘x’ empty or full AND is alignment allowed now,
f. Perform MCA by either skip or repeat samples in mis-aligned channel, or by enabling audio sample rate conversion during a realignment process.

11. Method according to claim 10 including Simple Compensation steps of
a. At regular time interval longer than AC, preferably 100× longer than sample interval, assess average drift measure (AM=dd/cm), and reset cm counter and accumulated dd,
b. Limit magnitude of AM to minimise jitter below audio frequency to new value JM, and
c. send ADJUSTMENT MESSAGE (ADJ=JM).

12. Method according to claim 1 wherein the processing audio hardware includes analogue audio processing and requires control data to be sent from within the digital software to the end analogue device, converted from digital to analogue, processed in the analogue domain by that device then converted back to digital and sent back to the host software wherein the endpoint processing of processing audio hardware is synchronised without a universal clock all while maintaining accurate and glitch free clock synchronisation at low latency.

13. Method according to claim 12 wherein the step of comparing the measured clock rate of hardware processing audio and the measure clock rate of audio uses PID feedback mode.

14. Method according to claim 12 wherein the step of comparing the measured clock rate of hardware processing audio and the measure clock rate of audio uses ASRC (audio sample rate conversion) mode.

15. Method according to claim 12 wherein the step of comparing the measured clock rate of hardware processing audio and the measure clock rate of audio uses simple drift compensation mode.

16. Method according to claim 12 wherein the step of adjusting clock rate of hardware processing to match clock rate of audio includes an emergency buffer mode where samples can be repeated or skipped if over or underruns may occur.

17. Method according to claim 12 wherein the step of endpoint synchronised processing without a universal clock is by a multi-instance sync method that aligns audio channel buffers at certain times, either using audio skip/repeat, or using ASRC (audio sample rate conversion).
a. determine if multi-instance (multi-channel) alignment (MCA) is required by assessing if level of each used audio buffer from application on channel ‘x’ empty or full AND is alignment allowed now,
b. Perform MCA by either skip or repeat samples in mis-aligned channel, or by enabling audio sample rate conversion during a realignment process.

18. Method according to claim 17 including simple compensation steps of
a. At regular time interval longer than AC, preferably 100× longer than sample interval, assess average drift measure (AM=dd/cm), and reset cm counter,
b. Limit magnitude of AM to minimise jitter below audio frequency to new value JM, and
c. send ADJUSTMENT MESSAGE (ADJ=JM).
